(19) United States
(12) Patent Application Publication
(10) Pub. No.: US 2026/0090164 A1
(43) Pub. Date: Mar. 26, 2026

(54) LIGHT-EMITTING MASTER PLATE, LIGHT-EMITTING PANEL, AND CUTTING METHOD FOR LIGHT-EMITTING MASTER PLATE

(71) Applicant: Shanghai Tianma Microelectronics Co., Ltd., Shanghai (CN)

(72) Inventors: Yimiao Ding, Shanghai (CN); Zhicheng Wu, Shanghai (CN); Zhenhai Yin, Shanghai (CN); Ronghua Li, Shanghai (CN); Xiongping Li, Shanghai (CN); Feng Qin, Shanghai (CN); Wei Cheng, Shanghai (CN)

(73) Assignee: Shanghai Tianma Microelectronics Co., Ltd., Shanghai (CN)

(21) Appl. No.: 19/404,354

(22) Filed: Dec. 1, 2025

(30) Foreign Application Priority Data
Aug. 21, 2025 (CN) 202511180195.7

(51) Int. Cl. H10H 29/32; H10H 29/01; H10H 29/49

(52) U.S. Cl. CPC H10H 29/32; H10H 29/012; H10H 29/49

(57) ABSTRACT

Provided are a light-emitting master plate, a light-emitting panel, and a cutting method for a light-emitting master plate, and the present disclosure relates to the field of display technology. A light-emitting master plate includes at least one display area and multiple light-emitting areas arranged in an array in the display area. The light-emitting area includes a light-emitting element and a driver circuit. At least part of the light-emitting areas are provided with a cutting mark.

### CROSS-REFERENCE TO RELATED APPLICATION

This application claims priority to Chinese patent application No. 202511180195.7 filed with the China National Intellectual Property Administration (CNIPA) on Aug. 21, 2025, the disclosure of which is incorporated herein by reference in its entirety.

### TECHNICAL FIELD

The present disclosure relates to the technical field of panel cutting, and in particular, to a light-emitting master plate, a light-emitting panel, and a cutting method for a light-emitting master plate.

### BACKGROUND

A light-emitting diode (LED) is able to efficiently convert electrical energy into light energy. In the display field, Micro-LED and mini-LED may be directly used as sub-pixels in a display or as a backlight source for a liquid crystal display (LCD).

Currently, LED light-emitting panels are primarily in small to medium sizes, which can be used directly for display or spliced into large screens. For different application scenarios, panels of various shapes are required, necessitating the production of new molds and tape-outs tailored to different shapes, which results in high costs.

### SUMMARY

The present disclosure provides a light-emitting master plate, a light-emitting panel, and a cutting method for a light-emitting master plate.

The present disclosure provides a light-emitting master plate. The light-emitting master plate includes at least one display area and multiple light-emitting areas arranged in an array in a display area of the at least one display area.

A light-emitting area of the multiple light-emitting areas includes a light-emitting element and a driver circuit.

At least part of the multiple light-emitting areas are provided with a cutting mark.

The present disclosure further provides a light-emitting panel. The light-emitting panel is formed by cutting the preceding light-emitting master plate.

The light-emitting panel includes a display area. Multiple light-emitting areas are disposed in the display area. A light-emitting area of the multiple light-emitting areas includes a light-emitting element and a driver circuit.

At least part of the multiple light-emitting areas are provided with a cutting mark.

The present disclosure further provides a cutting method for the preceding light-emitting master plate. The cutting method includes acquiring a cutting solution, capturing and identifying at least part of cutting marks in the display area, determining at least one cutting mark of the at least part of cutting marks as a positioning cutting mark based on the captured and identified cutting marks, determining part of the at least part of cutting marks as path cutting marks based on the cutting solution and the positioning cutting mark, and cutting the light-emitting master plate based on the path cutting marks.

The present disclosure further provides a display device, and the display device includes the preceding light-emitting panel.

It is to be understood that the content described in this part is neither intended to identify key or important features of the embodiments of the present disclosure nor intended to limit the scope of the present disclosure. Other features of the present disclosure are apparent from the description provided hereinafter.

### BRIEF DESCRIPTION OF DRAWINGS

To illustrate technical solutions in the embodiments of the present disclosure more clearly, the accompanying drawings used in the description of the embodiments will be described below. The accompanying drawings described below illustrate only part of the embodiments of the present disclosure, and those skilled in the art may obtain other accompanying drawings based on the accompanying drawings described below on the premise that no creative work is done.

FIG. 1 is a first top view illustrating the structure of a light-emitting master plate according to an embodiment of the present disclosure.

FIG. 2 is a second top view illustrating the structure of a light-emitting master plate according to an embodiment of the present disclosure.

FIG. 3 is a diagram illustrating the structure of a light-emitting area according to an embodiment of the present disclosure.

FIG. 4 is a third top view illustrating the structure of a light-emitting master plate according to an embodiment of the present disclosure.

FIG. 5 is a schematic diagram illustrating the circuit structure of a driver circuit according to an embodiment of the present disclosure.

FIG. 6 is a first diagram illustrating the layer structure of a driver circuit according to an embodiment of the present disclosure.

FIG. 7 is a second diagram illustrating the layer structure of a driver circuit according to an embodiment of the present disclosure.

FIG. 8 is a third diagram illustrating the layer structure of a driver circuit according to an embodiment of the present disclosure.

FIG. 9 is a fourth diagram illustrating the layer structure of a driver circuit according to an embodiment of the present disclosure.

FIG. 10 is a fourth top view illustrating the structure of a light-emitting master plate according to an embodiment of the present disclosure.

FIG. 11 is a fifth top view illustrating the structure of a light-emitting master plate according to an embodiment of the present disclosure.

FIG. 12 is a sixth top view illustrating the structure of a light-emitting master plate according to an embodiment of the present disclosure.

FIG. 13 is a seventh top view illustrating the structure of a light-emitting master plate according to an embodiment of the present disclosure.

FIG. 14 is an eighth top view illustrating the structure of a light-emitting master plate according to an embodiment of the present disclosure.

FIG. 15 is a ninth top view illustrating the structure of a light-emitting master plate according to an embodiment of the present disclosure.

FIG. 16 is a tenth top view illustrating the structure of a light-emitting master plate according to an embodiment of the present disclosure.

FIG. 17 is a first top view illustrating the structure of a light-emitting panel according to an embodiment of the present disclosure.

FIG. 18 is a second top view illustrating the structure of a light-emitting panel according to an embodiment of the present disclosure.

FIG. 19 is a third top view illustrating the structure of a light-emitting panel according to an embodiment of the present disclosure.

FIG. 20 is a flowchart of a cutting method for a light-emitting master plate according to an embodiment of the present disclosure.

FIG. 21 is a diagram illustrating the structure of a display device according to an embodiment of the present disclosure.

### DETAILED DESCRIPTION

The solutions in the embodiments of the present disclosure will be described clearly and completely in connection with the accompanying drawings in the embodiments of the present disclosure from which the solutions will be apparent to those skilled in the art. The embodiments described below are only part, not all, of embodiments of the present disclosure. Based on the embodiments described herein, all other embodiments obtained by those skilled in the art without creative work are within the scope of the present disclosure.

It is to be noted that the terms such as “first” and “second” in the description, claims, and preceding drawings of the present disclosure are used to distinguish between similar objects and are not necessarily used to describe a particular order or sequence. It is to be understood that the data used in this manner is interchangeable when appropriate so that embodiments of the present disclosure described herein can also be implemented in a sequence other than those illustrated or described herein. Additionally, terms “comprising”, “including”, and any other variations thereof are intended to encompass a non-exclusive inclusion. For example, a process, method, system, product, or device that includes a series of steps or units not only includes the expressly listed steps or units but may also include other steps or units that are not expressly listed or are inherent to such a process, method, product, or device.

As described in the background, LED light-emitting panels are primarily in small to medium sizes, which are able to be used directly for display or spliced into large screens. When applied to devices such as wearable devices and automotive displays, it is necessary to prepare light-emitting panels with special shapes, such as circular, rounded rectangular, trapezoidal, or triangular shapes, based on the shapes of the devices. For large-scale splicing, light-emitting panels in the middle may be rectangular with regular sizes, while panels at the edges may need to be prepared as non-standard sizes or shapes, such as rounded rectangles or small-sized rectangles.

Typically, special-shaped cutting is required to obtain light-emitting panels of different shapes or sizes. When different shapes or sizes are required, it is necessary to design and prepare different cutting mark masks, enabling the formation of corresponding cutting marks in the light-emitting panel. During cutting, the cutting equipment is able to capture the cutting marks for alignment correction and cut at the positions of the cutting marks to form light-emitting panels of corresponding shapes or sizes.

However, in the related art, a single cutting mark mask is only able to form a light-emitting panel of a specific shape or size. To form light-emitting panels of different shapes or sizes, different cutting mark masks need to be designed and prepared. The positions of the structures used to form cutting marks in different cutting mark masks are at least partially different. That is, for each shape or size of the light-emitting panel to be prepared, the positions of the structures used to form cutting marks in the cutting mark mask need to be redesigned, and new cutting mark masks need to be prepared to form light-emitting panels of different shapes or sizes, resulting in high costs.

To address the preceding technical problem, an embodiment of the present disclosure provides a light-emitting master plate. The light-emitting master plate includes at least one display area and multiple light-emitting areas arranged in an array in the display area. The light-emitting area includes a light-emitting element and a driver circuit. At least part of the light-emitting areas are provided with a cutting mark.

The technical solution of the present disclosure is adopted, where multiple cutting marks are provided in the display area, and the number of cutting marks is greater than the number required for actual cutting. A redundant design is adopted for the cutting marks. A light-emitting master plate provided with cutting marks having the same number and positions supports multiple cutting solutions. That is, for different shape requirements from different customers, the same light-emitting master plate can be cut without the need to design different cutting mark masks for different shape requirements, which helps improve production efficiency and reduce production costs. Moreover, the cutting marks are disposed in the array-arranged light-emitting areas so that the positions of the cutting marks can be correspondingly set with respect to the positions of the light-emitting areas, that is, the positions of the cutting marks can correspond to the light-emitting elements and/or driver circuits within the light-emitting areas. During special-shaped cutting on the light-emitting master plate, this configuration helps reduce damage to the light-emitting elements and driver circuits within the light-emitting areas, thereby improving product yield.

The above constitutes the core concept of the present disclosure. Based on the embodiments in the present disclosure, all other embodiments obtained by those of ordinary skill in the art without creative efforts fall within the scope of the present disclosure. Technical solutions in the embodiments of the present disclosure will be described clearly and completely in conjunction with drawings in the embodiments of the present disclosure.

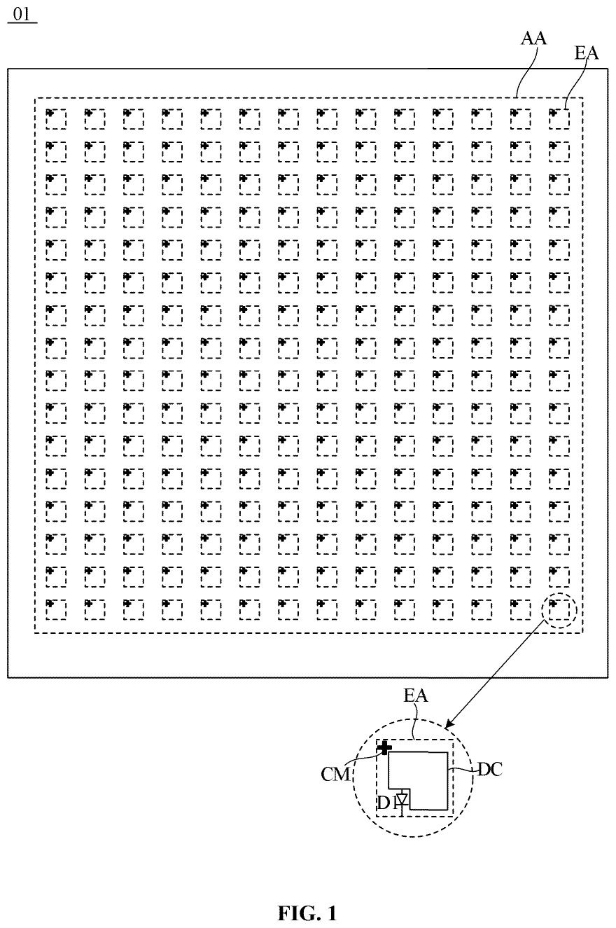

FIG. 1 is a first top view illustrating the structure of a light-emitting master plate according to an embodiment of the present disclosure. With reference to FIG. 1, the light-emitting master plate 01 includes at least one display area AA and multiple light-emitting areas EA arranged in an array in the display area AA. The light-emitting area EA includes a light-emitting element D1 and a driver circuit DC. At least part of the light-emitting areas EA are provided with a cutting mark CM.

The light-emitting master plate 01 refers to an original substrate or master plate that includes light-emitting materials and is able to achieve light-emitting characteristics. The light-emitting master plate 01 may be an original master plate that has completed layer preparation but has not yet been cut and includes one or multiple display areas AA. Alternatively, the light-emitting master plate 01 may also be an intermediate master plate that has undergone basic cutting after layer preparation but still requires further cutting to achieve the final shape of a single light-emitting panel. The intermediate master plate may also include one or multiple display areas AA.

The display area AA refers to the area in the light-emitting master plate 01 that is actually used for light emission. In an embodiment, the display area AA may directly display images. In another embodiment, the display area AA may also serve as a backlight source and display images through a liquid crystal layer, a filter layer, or other layers.

The light-emitting area EA refers to an independently controllable basic unit within the display area AA. The light-emitting area EA includes at least one light-emitting element D1 and at least one driver circuit DC. In an embodiment, the light-emitting area EA may be the smallest independently controllable basic unit in the display area AA. In this case, a light-emitting area EA may include only one driver circuit DC. In another embodiment, the light-emitting area EA may also be a basic control unit capable of independently controlling color in the display area AA. In this case, the light-emitting area EA may include multiple independently controllable smallest basic units, and a light-emitting area EA may include multiple driver circuits DC. When the display area AA is used to directly display images, the light-emitting area EA may be a sub-pixel setting area (where the light-emitting area EA includes one driver circuit DC) or a pixel unit setting area (where the light-emitting area EA includes multiple driver circuits DC).

The light-emitting element D1 includes, but is not limited to, an OLED, a Micro-LED, and a mini-LED. The driver circuit DC is able to drive the light-emitting element D1 to emit light for display. In an embodiment, the driver circuit DC includes at least one transistor, and the driver circuit DC is able to provide a drive current to the light-emitting element D1 electrically connected to the driver circuit DC. In the same light-emitting area EA, the light-emitting area EA may include the light-emitting element D1 and the active regions of all transistors in the driver circuit DC.

It should be understood that to simplify the drawings and facilitate explanation, FIG. 1 only illustrates part of the structure of the light-emitting master plate 01. The light-emitting master plate 01 may also include structures such as a base substrate and signal lines, which are not individually described or shown.

In one or more embodiments, multiple light-emitting areas EA in the display area AA may be provided with cutting marks CM, that is, the display area AA includes multiple cutting marks CM. In the same display area AA, the number of cutting marks CM may be redundantly designed. When the light-emitting master plate 01 is cut using the cutting marks CM in the light-emitting areas EA, only part of the cutting marks CM in the same display area AA may be used to determine the cutting position and cutting path. For a light-emitting master plate 01 with the same number and positions of cutting marks CM, different numbers and/or different positions of cutting marks CM may be used to determine different positions and cutting paths so that the light-emitting master plate 01 with the same number and positions of cutting marks CM can support multiple cutting solutions, and the light-emitting master plate 01 can be cut into special-shaped light-emitting panels of different shapes. Moreover, the cutting marks CM are provided in the light-emitting areas EA, and the cutting marks CM may be set corresponding to part of the light-emitting areas EA. For example, different cutting marks CM may be set at the same position in different light-emitting areas EA. During special-shaped cutting of the light-emitting master plate 01, this configuration helps reduce damage to the light-emitting elements D1 and the driver circuits DC in the light-emitting areas EA.

In one or more embodiments, with reference to FIG. 1, the light-emitting master plate 01 described in this embodiment may be an intermediate master plate that has undergone basic cutting based on the number of display areas AA after layer preparation but still requires further cutting to achieve the final shape of a single light-emitting panel. The intermediate master plate may include one display area AA, facilitating the formation of the final shape of a single light-emitting panel. Before cutting, the cutting equipment may first identify all cutting marks CM in the display area AA, then select part of cutting marks CM based on the designed shape of the light-emitting panel as the marks needed for this cutting, and determine the cutting position and cutting path based on the positions of the selected cutting marks CM, thereby ensuring that the shape of the cut light-emitting panel matches the designed shape. The redundantly designed cutting marks CM allow for different cutting positions and cutting paths within the display area AA, and the cutting marks CM located within the display area AA also enable non-linear cutting paths within the display area AA, facilitating special-shaped cutting and enabling the cut light-emitting panel to have a non-rectangular shape.

In one or more embodiments, the light-emitting master plate 01 may also be an original master plate that has not been cut after layer preparation, and the original master plate may include multiple display areas AA. Master plate cutting marks may be provided between adjacent display areas AA. Before special-shaped cutting is performed using the cutting marks CM in the light-emitting areas EA, the light-emitting master plate 01 may first be cut into an intermediate master plate including one display area AA using the master plate cutting marks between adjacent display areas AA, and then special-shaped cutting is performed using the cutting marks CM in the light-emitting areas EA, which simplifies special-shaped cutting and reduces cutting difficulty. In an embodiment, the shape of the master plate cutting marks between adjacent display areas AA is different from the shape of the cutting marks CM in the light-emitting areas EA. In this manner, rapid identification of the master plate cutting marks between adjacent display areas AA is facilitated, and identification efficiency is improved.

It should be noted that FIG. 1 only exemplarily illustrates that the shape of the light-emitting master plate 01 and the shape of the display area AA are rectangular, but it is not limited thereto. In other embodiments, the light-emitting master plate 01 and/or the display area AA may also have non-rectangular shapes such as circular, triangular, or pentagonal, and the embodiments of the present disclosure do not specifically limit the shape of the light-emitting master plate 01 or the shape of the display area AA.

It should also be noted that FIG. 1 only exemplarily illustrates the cutting mark CM as a cross shape. In other optional embodiments, the cutting mark CM may also have shapes such as an “L” shape, an “E” shape, a shape consisting of three horizontal and one vertical bar, or a shape of a rectangular frame with one horizontal rib. The embodiments of the present disclosure do not specifically limit the shape of the cutting mark CM.

In the light-emitting master plate provided by the embodiment of the present disclosure, multiple cutting marks are provided in the display area, and the number of cutting marks is greater than the number required for actual cutting. A redundant design is adopted for the cutting marks. A light-emitting master plate provided with cutting marks having the same number and positions supports multiple cutting solutions. That is, for different shape requirements from different customers, the same light-emitting master plate can be cut without the need to design different cutting mark masks for different shape requirements, which helps improve production efficiency and reduce production costs. Moreover, the cutting marks are disposed in the array-arranged light-emitting areas so that the positions of the cutting marks can be correspondingly set with respect to the positions of the light-emitting areas, that is, the positions of the cutting marks can correspond to the light-emitting elements and/or driver circuits within the light-emitting areas. During special-shaped cutting of the light-emitting master plate, this configuration helps reduce damage to the light-emitting elements and driver circuits within the light-emitting areas, thereby improving product yield.

In one or more embodiments, with continued reference to FIG. 1, in a row where a light-emitting area EA provided with the cutting mark CM is located, at least two light-emitting areas EA are each provided with the cutting mark CM; and/or, in a column where a light-emitting area EA provided with the cutting mark CM is located, at least two light-emitting areas EA are each provided with the cutting mark CM.

Exemplarily, in the same row of light-emitting areas EA, either none of the light-emitting areas EA are provided with cutting marks CM, or two or more light-emitting areas EA are provided with cutting marks CM. When the cutting path is determined using any one cutting mark CM, the cutting path may extend along the row direction. In the same column of light-emitting areas EA, either none of the light-emitting areas EA are provided with cutting marks CM, or two or more light-emitting areas EA are provided with cutting marks CM. When the cutting path is determined using any one cutting mark CM, the cutting path may extend along the column direction. This configuration allows the cutting path to extend as much as possible along the row direction or column direction and reduces cutting paths extending in a diagonal direction. During special-shaped cutting of the light-emitting master plate 01, this configuration helps reduce damage to the light-emitting elements D1 and driver circuits DC in the light-emitting areas EA.

On the basis of the preceding embodiments, among light-emitting areas EA located in the same row, at least two of the light-emitting areas EA are each provided with the cutting mark CM; and/or, among light-emitting areas EA located in the same column, at least two of the light-emitting areas EA are each provided with the cutting mark CM.

Exemplarily, in each row of light-emitting areas EA, two or more light-emitting areas EA provided with cutting marks CM exist, and/or, in each column of light-emitting areas EA, two or more light-emitting areas EA provided with cutting marks CM exist. Thus, when any row or column of light-emitting areas EA is cut, the cutting path can extend along the row direction or column direction, helping to reduce damage to the light-emitting elements D1 and driver circuits DC in the light-emitting areas EA.

In one or more embodiments, with continued reference to FIG. 1, each light-emitting area EA located in the display area AA is provided with the cutting mark CM.

Exemplarily, each light-emitting area EA in the display area AA is provided with a cutting mark CM, and the cutting marks CM may be arranged in an array in the display area AA, similar to the light-emitting areas EA. Thus, cutting solutions for any shape can be achieved to satisfy various design requirements.

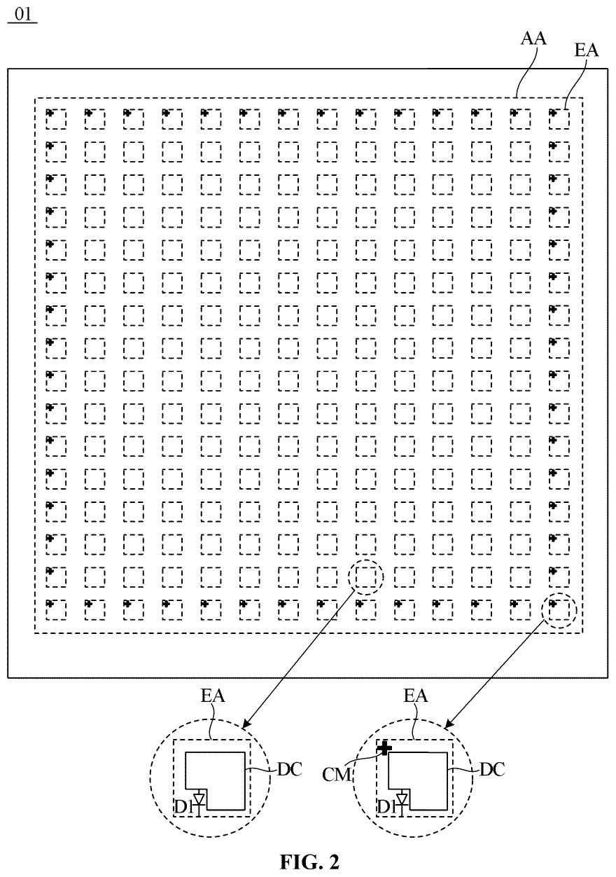

In one or more embodiments, FIG. 2 is a second top view illustrating the structure of a light-emitting master plate according to an embodiment of the present disclosure. With reference to FIG. 2, each light-emitting area EA located at an edge of the display area AA is provided with the cutting mark CM.

Exemplarily, in the display area AA, the light-emitting areas EA adjacent to the edge of the display area AA are provided with cutting marks CM, while the light-emitting areas EA that are not adjacent to the edge of the display area AA may not be provided with cutting marks CM. Thus, cutting marks CM are provided only in the light-emitting areas EA located at the edge positions of the display area AA. On the one hand, any two cutting marks CM can determine a cutting path. In particular, any two cutting marks CM located at different edges of the display area AA can determine multiple cutting paths and achieve multiple cutting solutions. On the other hand, this configuration can reduce the number of cutting marks CM in the display area AA and the number of light-emitting areas EA provided with cutting marks CM and help simplify the design of the cutting marks CM, thereby simplifying the design of the cutting mark mask and reducing production costs.

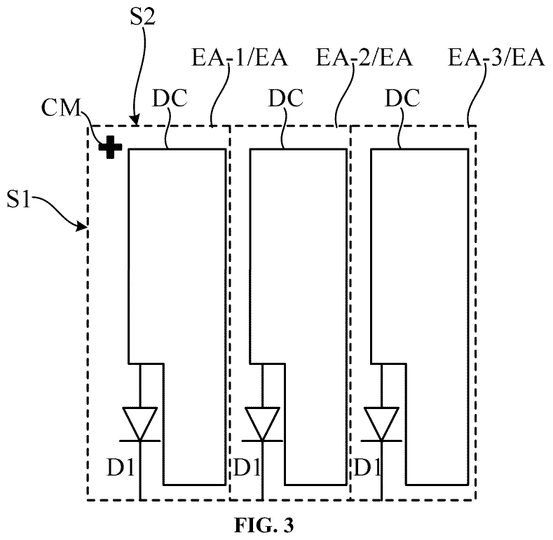

In one or more embodiments, FIG. 3 is a diagram illustrating the structure of a light-emitting area according to an embodiment of the present disclosure. With reference to FIG. 3, the light-emitting area EA includes multiple light-emitting elements D1 and multiple driver circuits DC, and a light-emitting area EA provided with the cutting mark CM has only one cutting mark CM.

Exemplarily, the light-emitting area EA includes three light-emitting elements D1 and three driver circuits DC, and the light-emitting area EA has only one cutting mark CM. The light-emitting area EA includes one pixel unit. The three light-emitting elements D1 in the light-emitting area EA may emit light of different colors or present different colors such as red, green, and blue through a liquid crystal layer or a filter layer. The light-emitting area EA may directly present multiple colors within the display color gamut or present multiple colors within the display color gamut through a liquid crystal layer or a filter layer. The light-emitting area EA is provided with multiple light-emitting elements D1 and driver circuits DC, and only one cutting mark CM is set in the light-emitting area EA. This configuration helps ensure the integrity of the multiple light-emitting elements D1 and multiple driver circuits DC in the light-emitting area EA during cutting. That is, the multiple light-emitting elements D1 and multiple driver circuits DC in the same light-emitting area EA can either be cut away together or remain uncut together, thereby ensuring the integrity of the pixel unit and avoiding color deviation due to a reduced number of light-emitting elements D1 and driver circuits DC of the light-emitting area EA at the edge of the light-emitting panel after cutting.

It should be noted that FIG. 3 only exemplarily illustrates that the light-emitting area EA includes three light-emitting elements D1 and three driver circuits DC. In one or more embodiments, the light-emitting area EA may also include four light-emitting elements D1 and four driver circuits DC. Alternatively, the light-emitting area EA may also include five light-emitting elements D1 and five driver circuits DC. Alternatively, the light-emitting area EA may also include six light-emitting elements D1 and six driver circuits DC. When the light-emitting area EA includes four light-emitting elements D1 and four driver circuits DC, the four light-emitting elements D1 in the light-emitting area EA may directly or indirectly present light of different colors, such as red, green, blue, and white. When the light-emitting area EA includes five light-emitting elements D1 and five driver circuits DC, the five light-emitting elements D1 may emit, for example, red, green, blue, yellow, and cyan. When the light-emitting area EA includes six light-emitting elements D1 and six driver circuits DC, the six light-emitting elements D1 may emit, for example, red, green, blue, yellow, cyan, and magenta. The embodiments of the present disclosure do not limit the number of light-emitting elements D1, the number of driver circuits DC, or the colors emitted directly or indirectly by the light-emitting elements D1 in the light-emitting area EA.

In one or more embodiments, the number of light-emitting elements D1 and the number of driver circuits DC in the light-emitting area EA may also be different. For example, one driver circuit DC may be electrically connected to multiple light-emitting elements D1 and drive the multiple light-emitting elements D1 to emit light. The embodiments of the present disclosure do not limit the number of light-emitting elements D1 connected to and driven by one driver circuit DC.

On the basis of the preceding embodiments, with continued reference to FIG. 3, the light-emitting area EA includes a first edge S1 and a second edge S2 that are adjacent to each other. The light-emitting area EA includes multiple sub-light-emitting areas, and the sub-light-emitting area includes at least one light-emitting element D1 and one driver circuit DC. A sub-light-emitting area adjacent to both the first edge S1 and the second edge S2 is a first sub-light-emitting area EA-1. The first sub-light-emitting area EA-1 is provided with the cutting mark CM. In the first sub-light-emitting area EA-1, the cutting mark CM is located on a side of the driver circuit DC closer to the first edge S1, and/or the cutting mark CM is located on a side of the driver circuit DC closer to the second edge S2.

Exemplarily, the light-emitting area EA includes three light-emitting elements D1 and three driver circuits DC. Correspondingly, the light-emitting area EA may include a first sub-light-emitting area EA-1, a second sub-light-emitting area EA-2, and a third sub-light-emitting area EA-3 arranged sequentially from left to right. The first edge S1 may be the left edge of the light-emitting area EA, and the second edge S2 may be the upper edge of the light-emitting area EA. The first sub-light-emitting area EA-1 is located at an edge position of the light-emitting area EA, and the cutting mark CM is disposed in the first sub-light-emitting area EA-1 on a side of the driver circuit DC closer to the edge, making the cutting mark CM located at the position closest to the edge of the light-emitting area EA. As shown in FIG. 3, the cutting mark CM may be located at a corner position of the light-emitting area EA. Thus, during special-shaped cutting of the light-emitting master plate 01, this configuration helps reduce damage to the light-emitting elements D1 and the driver circuits DC in the light-emitting area EA, preserve the integrity of the light-emitting elements D1 and the driver circuits DC in the light-emitting area EA, and avoid color deviation at the edge of the light-emitting panel after cutting.

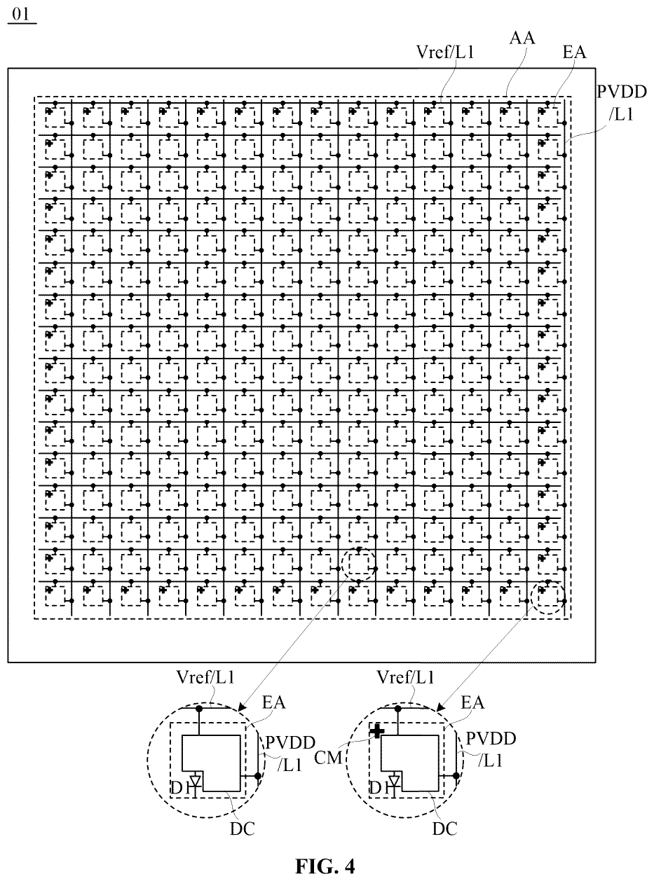

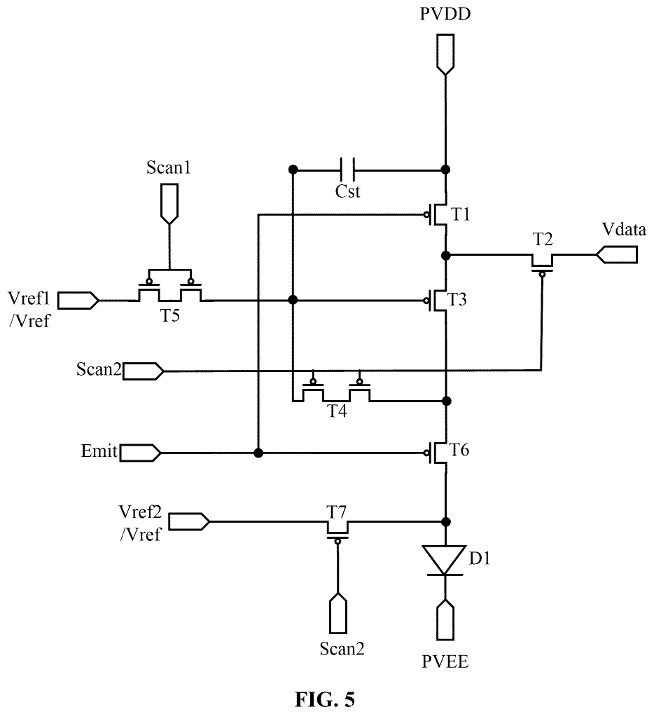

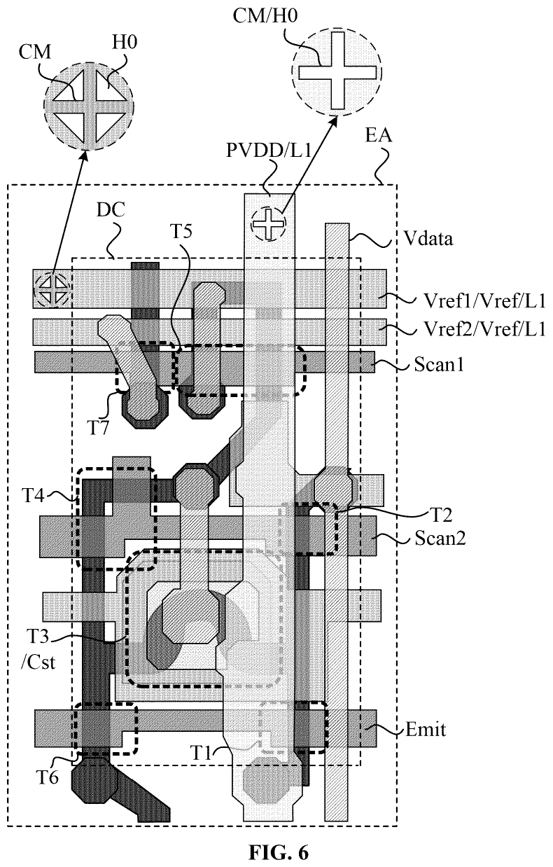

In one or more embodiments, FIG. 4 is a third top view illustrating the structure of a light-emitting master plate according to an embodiment of the present disclosure. FIG. 5 is a schematic diagram illustrating the circuit structure of a driver circuit according to an embodiment of the present disclosure. FIG. 6 is a first diagram illustrating the layer structure of a driver circuit according to an embodiment of the present disclosure. With reference to FIG. 4 to FIG. 6, the light-emitting master plate 01 also includes multiple first signal lines L1 located in the display area AA. The first signal line L1 is electrically connected to at least part of the driver circuits DC. At least part of the first signal lines L1 include a hollow structure H0, and the cutting mark CM is disposed in the hollow structure H0.

Exemplarily, when the display area AA may directly display images, the driver circuit DC may be a 7T1C circuit as shown in FIG. 5 and FIG. 6, but the driver circuit is not limited thereto. When the driver circuit DC is a 7T1C circuit, the driver circuit may include a drive transistor T3, a write transistor T2, an initialization transistor T5, a compensation transistor T4, a first light emission control transistor T1, a second light emission control transistor T6, a reset transistor T7, and a capacitor Cst. The gate of the initialization transistor T5 may be electrically connected to a first scanning signal line Scan1. The gate of the write transistor T2 and the gate of the reset transistor T7 may be electrically connected to a second scanning signal line Scan2. The gate of the first light emission control transistor T1 and the gate of the second light emission control transistor T6 may be electrically connected to a light emission control line Emit. The capacitor Cst and a first electrode of the first light emission control transistor T1 are both electrically connected to a first power line PVDD. A first electrode of the write transistor T2 is electrically connected to a data signal line Data. A first electrode of the initialization transistor T5 is electrically connected to a first reset signal line Vref1. A first electrode of the reset transistor T7 is electrically connected to a second reset signal line Vref2. A second electrode of the reset transistor T7 and the light-emitting element D1 are electrically connected to a second power line PVEE. The first reset signal line Vref1 and the second reset signal line Vref2 are both reset signal lines Vref, and their potentials may be the same or different, which is not limited by the embodiments of the present disclosure.

The first signal line L1 may be any signal line connected to the driver circuit DC. In one or more embodiments, the first signal line L1 is used for transmitting a signal of a fixed potential. Exemplarily, the first signal line L1 may be the first power line PVDD, the second power line PVEE, or the reset signal line Vref connected to the driver circuit DC. As shown in FIG. 6, a hollow structure H0 may be disposed on the first power line PVDD and/or the reset signal line Vref, and the cutting mark CM is disposed in the hollow structure H0.

The cutting mark CM is disposed on the first signal line L1 in the display area AA. This configuration helps save space in the display area AA, reduces the impact of the cutting mark CM on the light-emitting element D1 and driver circuit DC in the light-emitting area EA, improves resolution, and helps avoid the risk of discharge from large conductive metals during the chemical vapor deposition (CVD) process. Additionally, the first signal line L1 is used for transmitting the signal of the fixed potential and is typically connected to multiple driver circuits DC, resulting in a higher load. The first signal line L1 may be set as a relatively wide line, which helps increase the size of the cutting mark CM disposed on the first signal line L1 and facilitates identification and capturing by the cutting equipment.

It should be understood that the hollow structure H0 may be the cutting mark CM or the cutting mark CM may be formed in the hollow structure H0 by the provision of the hollow structure H0. The embodiments of the present disclosure do not limit the specific setting method of the cutting mark CM. When the cutting mark CM is formed in the hollow structure H0 by the provision of the hollow structure H0, the cutting mark CM may be connected to the first signal line L1 provided with the hollow structure H0, or the cutting mark CM may not be connected to the first signal line L1 provided with the hollow structure H0, which is not limited by the embodiments of the present disclosure.

It should be noted that FIG. 6 only exemplarily illustrates that the cutting mark CM may be made in the same process as the first signal line L1. In other exemplary embodiments, the cutting mark CM may be made in a different process from the first signal line L1. The embodiments of the present disclosure do not limit the material or manufacturing process of the cutting mark.

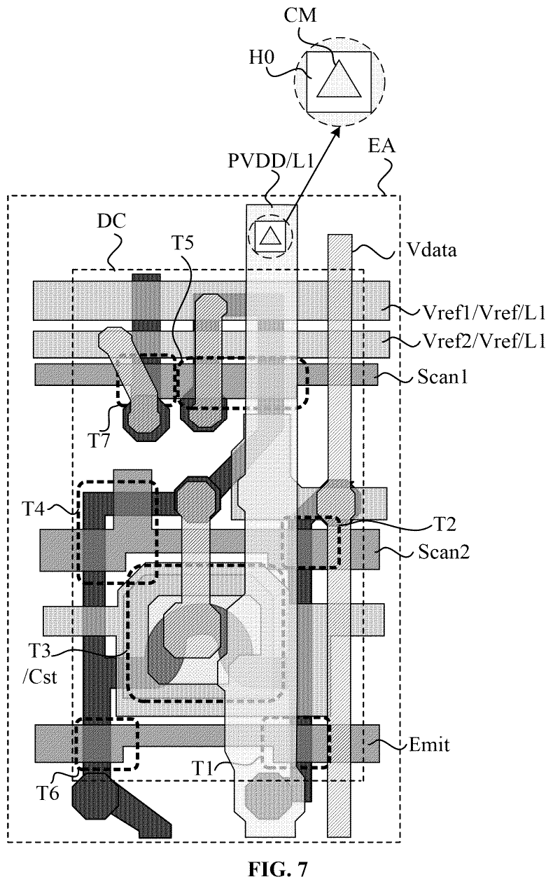

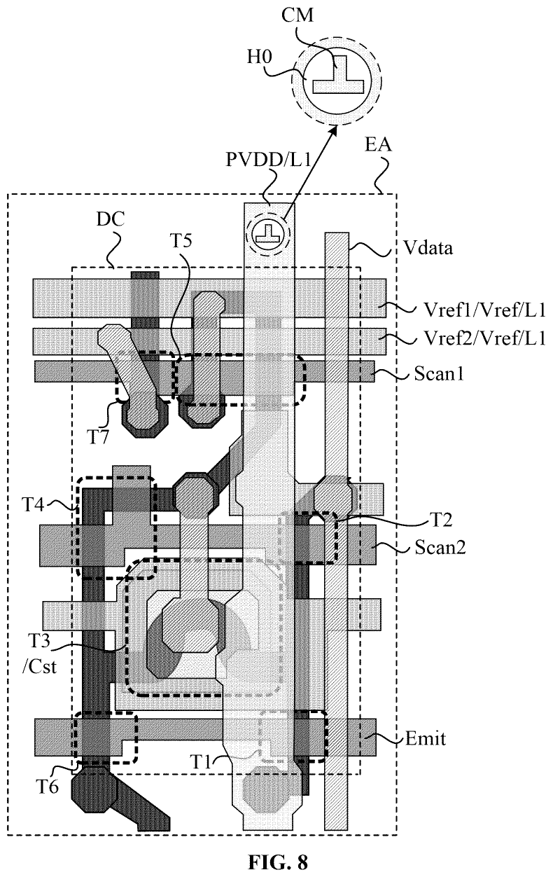

It should also be noted that when the hollow structure H0 is the cutting mark CM, the shape of the hollow structure H0 is the shape of the cutting mark CM. When the cutting mark CM is formed in the hollow structure H0 by the provision of the hollow structure H0, the shape of the hollow structure H0 has no direct relationship with the shape of the cutting mark CM. The shape of the hollow structure H0 and the shape of the cutting mark CM may be the same or completely different. For example, as shown in FIG. 6 to FIG. 8, the shape of the hollow structure H0 may be rectangular, circular, triangular, or diamond-shaped, and the cutting mark CM disposed in the hollow structure H0 may be a triangle, a cross, or a special shape that is the same or different from the shape of the hollow structure H0.

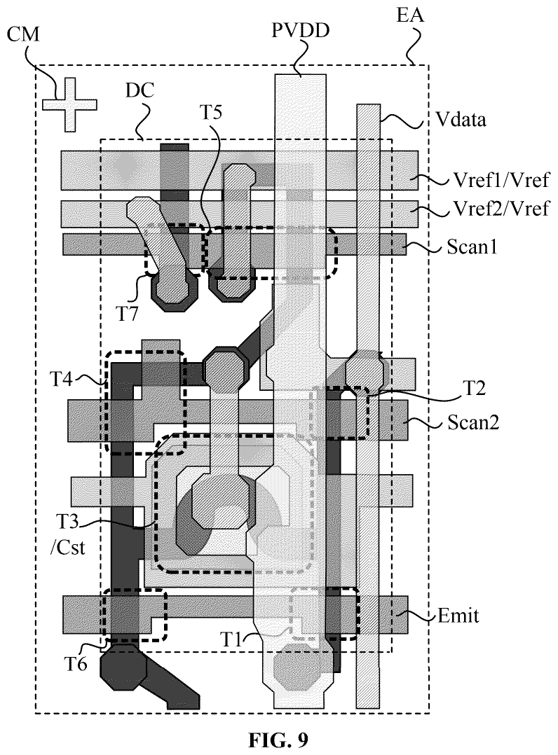

In one or more embodiments, FIG. 9 is a fourth diagram illustrating the layer structure of a driver circuit according to an embodiment of the present disclosure. With continued reference to FIG. 6 to FIG. 9, the light-emitting master plate 01 includes multiple conductive layers and at least one active layer. The conductive layer includes conductive structures, such as Scan1, Scan2, Vref, and PVDD. The active layer includes active structures, such as active structures of T1, T2, T3, T4, T5, T6, and T7. In a direction perpendicular to a plane where the light-emitting master plate 01 is located, the projection of the cutting mark CM on the plane where the light-emitting master plate is located does not overlap with the projection of the conductive structure in the driver circuit DC on the plane where the light-emitting master plate 01 is located and the projection of the active structure on the plane where the light-emitting master plate 01 is located.

Exemplarily, the cutting mark CM generally includes a metal structure. During cutting of the light-emitting master plate 01, melting or spiking at the cutting edge may occur. The projection of the cutting mark CM on the plane where the light-emitting master plate is located does not overlap with the projection of the conductive structure in the driver circuit DC on the plane where the light-emitting master plate 01 is located and the projection of the active structure on the plane where the light-emitting master plate 01 is located. In this manner, the conductive structure, active structure, and other structures in the driver circuit DC are prevented from being cut during cutting, thereby preventing short circuits between the cutting mark CM and the conductive structure, active structure, and other structures in the driver circuit DC, as well as short circuits between the conductive structure and active structure, active structure, and other structures in the driver circuit DC. Thus, the normal operation of the driver circuit DC at the cutting edge is not affected.

In one or more embodiments, the cutting mark CM may be disposed in the hollow structure H0 of the first signal line L1 located outside the driver circuit DC, as shown in FIG. 6 to FIG. 8.

Exemplarily, during cutting, cutting may be performed along a direction parallel to the plane where the light-emitting master plate 01 is located and intersecting with the extension direction of the first signal line L1 to avoid the impact of cutting on the width of the first signal line L1 and a significant voltage drop on the signal of the first signal line L1. In an embodiment, in a direction perpendicular to the plane where the light-emitting master plate 01 is located, the projection of the cutting mark CM in the hollow structure H0 of the first signal line L1 on the plane where the light-emitting master plate is located does not overlap with the projections of other conductive structures (except the first signal line L1) and active structures inside or outside the driver circuit DC on the plane where the light-emitting master plate 01 is located, thereby avoiding short circuits between the first signal line and other conductive structures or active structures after cutting.

In one or more embodiments, the cutting mark CM may be independently disposed outside the signal lines, as shown in FIG. 9.

Exemplarily, during cutting, cutting may be performed along the row direction or column direction, thereby avoiding cutting into the driver circuit DC. In an embodiment, in a direction perpendicular to the plane where the light-emitting master plate 01 is located, the projection of the cutting mark CM on the plane where the light-emitting master plate is located does not overlap with the projections of the conductive structures and active structures inside or outside the driver circuit DC on the plane where the light-emitting master plate 01 is located, thereby avoiding short circuits in the conductive structures or active structures.

In one or more embodiments, in a direction perpendicular to the plane where the light-emitting master plate 01 is located, the projection of the cutting mark CM on the plane where the light-emitting master plate is located does not overlap with the projection of the light-emitting element D1 on the plane where the light-emitting master plate 01 is located.

It should be noted that FIG. 9 only exemplarily illustrates that the cutting mark CM is made of the same material as the first power line PVDD and may be made in the same process, but it is not limited thereto. The cutting mark CM may be made of the same material as any layer structure and made in the same process, or the cutting mark CM may be made in a separate process and is not prepared in the same process as any other layer structure, which is not limited by the embodiments of the present disclosure.

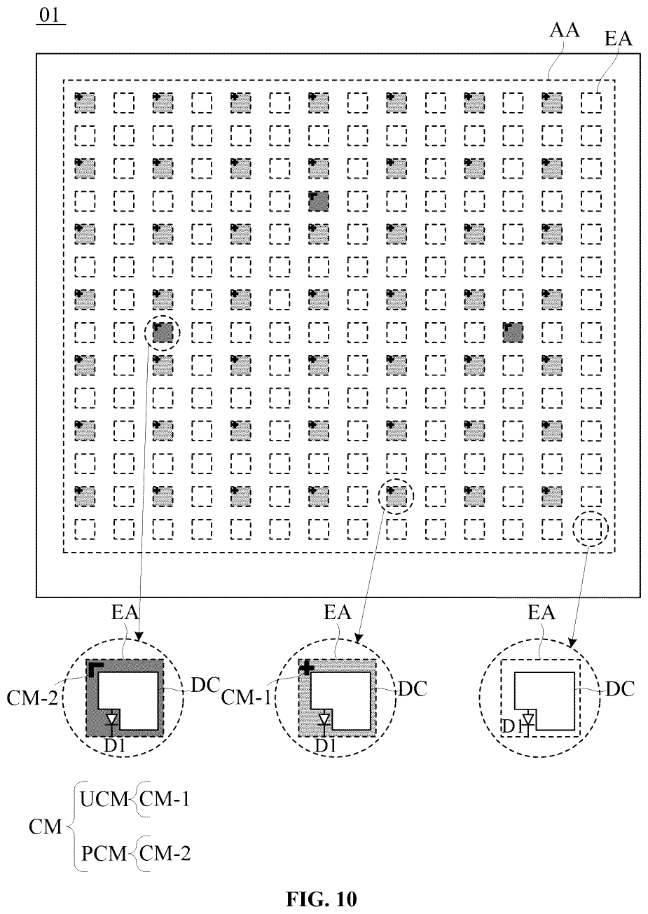

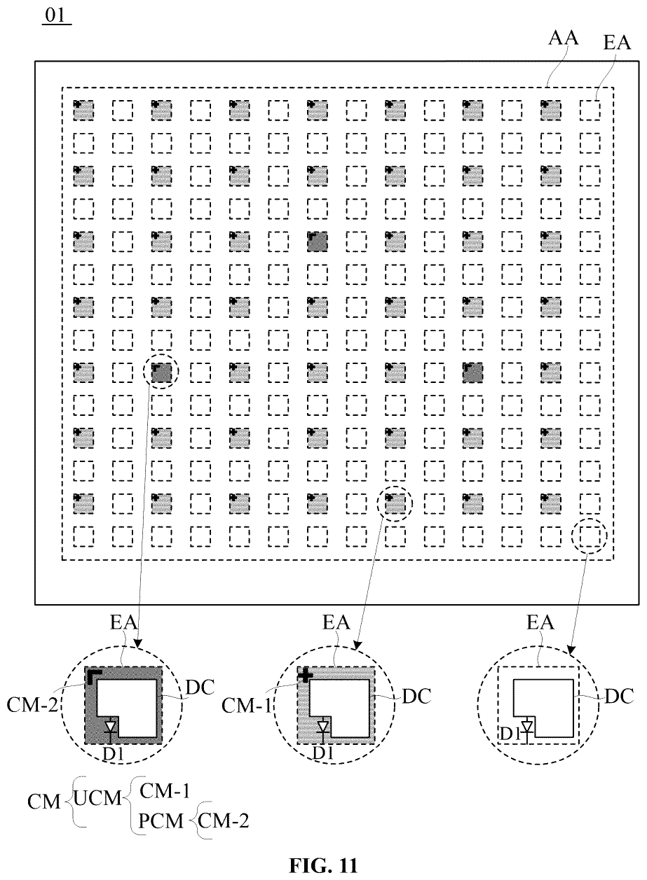

In one or more embodiments, FIG. 10 is a fourth top view illustrating the structure of a light-emitting master plate according to an embodiment of the present disclosure. FIG. 11 is a fifth top view illustrating the structure of a light-emitting master plate according to an embodiment of the present disclosure. With reference to FIG. 10 and FIG. 11, the cutting mark CM includes a universal cutting mark UCM and a positioning cutting mark PCM. The universal cutting mark UCM at least includes a first cutting mark CM-1. The positioning cutting mark PCM includes a second cutting mark CM-2. The shape of the first cutting mark CM-1 is different from the shape of the second cutting mark CM-2. In the same display area AA, the number of the first cutting marks CM-1 is greater than the number of the second cutting marks CM-2.

In the same display area AA, a smaller number of second cutting marks CM-2 and a larger number of first cutting marks CM-1 are provided. The second cutting mark CM-2 may be used as a positioning cutting mark PCM. The positioning cutting mark PCM may be used to locate the position of the light-emitting master plate 01 or to locate the cutting marks CM needed for cutting, thereby locating the cutting position. The first cutting mark CM-1 may be used as a universal cutting mark UCM. The universal cutting mark UCM includes the marks actually needed for cutting, and a cutting path may be determined using part of the universal cutting marks UCM.

Exemplarily, the positioning cutting mark PCM may be disposed in the light-emitting area EA located at a special position in the display area AA. For example, the positioning cutting mark PCM may be disposed in the light-emitting area EA in the middle position, near the edge position, or in the corner position, thereby facilitating rapid identification by the cutting equipment. Based on the position of the positioning cutting mark PCM, the position of the universal cutting mark UCM needed for special-shaped cutting is determined, and then the cutting position and cutting path are determined based on these universal cutting marks UCM. The first cutting mark CM-1 and the second cutting mark CM-2 are provided in the display area AA so that the multiple cutting marks CM in the display area AA are divided into universal cutting marks UCM and positioning cutting marks PCM. This configuration enables rapid positioning of the cutting marks CM needed for cutting, supports multiple cutting paths, and facilitates precise cutting.

It should be understood that the fill patterns of the light-emitting areas EA in the drawings are only used to indicate that the light-emitting area EA is provided with a cutting mark CM. Different fill patterns in the light-emitting areas EA are only used to indicate that the shapes of the cutting marks CM provided in the light-emitting areas EA are different. Light-emitting areas EA without fill patterns are not provided with cutting marks CM, while the light-emitting elements EA and driver circuits DC in light-emitting areas EA with different fill patterns or without fill patterns may be the same.

In one or more embodiments, as shown in FIG. 10, the universal cutting mark UCM may include only the first cutting mark CM-1, and the positioning cutting mark PCM may include only the second cutting mark CM-2. The positioning cutting mark PCM may be used only to locate the position of the cutting marks CM needed for special-shaped cutting and not to determine the cutting path.

In this case, the universal cutting mark UCM and the positioning cutting mark PCM may be located in different light-emitting areas EA, or part of universal cutting marks UCM and positioning cutting marks PCM may be located in the same light-emitting area EA. That is, the first cutting mark CM-1 and the second cutting mark CM-2 may be located in different light-emitting areas EA, or part of first cutting marks CM-1 and second cutting marks CM-2 may be located in the same light-emitting area EA. When the first cutting mark CM-1 and the second cutting mark CM-2 are located in different light-emitting areas EA, the first cutting mark CM-1 and the second cutting mark CM-2 may be disposed at the same position in different light-emitting areas EA. In an embodiment, the first cutting mark CM-1 and the second cutting mark CM-2 may be disposed in the hollow structure of the same signal line in different light-emitting areas EA. When part of first cutting marks CM-1 and second cutting marks CM-2 are located in the same light-emitting area EA, the first cutting mark CM-1 and the second cutting mark CM-2 may be disposed at different positions in the same light-emitting area EA. In an embodiment, the first cutting mark CM-1 and the second cutting mark CM-2 may be disposed in the hollow structures of different signal lines in the same light-emitting area EA or in different positions of the hollow structures of the same signal line.

In one or more embodiments, as shown in FIG. 11, the universal cutting mark UCM may include a first cutting mark CM-1 and a second cutting mark CM-2, and the positioning cutting mark PCM includes only the second cutting mark CM-2. That is, the positioning cutting mark PCM may be used as a universal cutting mark UCM, and the positioning cutting mark PCM may be used not only to locate the position of the cutting marks CM needed for special-shaped cutting but also to determine the cutting path.

Exemplarily, in the same display area AA, multiple universal cutting marks UCM may be arranged in an array with a specific pattern, and multiple first cutting marks CM-1 may be arranged in an array with a specific pattern. When the positioning cutting mark PCM is used as a universal cutting mark UCM, the second cutting marks CM-2 may be disposed at some positions where the first cutting marks CM-1 may otherwise be disposed to replace the first cutting marks CM-1, and the second cutting marks CM-2 are reused as the first cutting marks CM-1, making the universal cutting marks UCM arranged in an array. This configuration helps reduce the number of cutting marks CM in the display area AA, simplifies the design of the cutting mark mask, and reduces the impact of the cutting marks CM on structures such as the light-emitting elements D1 and driver circuits DC in the display area AA.

On the basis of the preceding embodiments, with continued reference to FIG. 10 and FIG. 11, an odd number of second cutting marks CM-2 are provided.

Exemplarily, the connection of the odd number of second cutting marks CM-2 may form an odd-sided polygon, and the shape formed by the connection of the odd number of second cutting marks CM-2 cannot be centrosymmetric. Even for symmetric polygons, such as a symmetric triangle or a symmetric pentagon, symmetry is only possible in one of the up-down or left-right directions, not in the other direction. Thus, when the light-emitting master plate 01 is placed in reverse in the up-down direction and/or left-right direction, the cutting equipment can identify a shape that is inconsistent with the preset positioning shape (the shape formed by the connection of the positioning cutting marks PCM when the light-emitting master plate 01 is correctly placed) through the positioning cutting marks PCM and stop the cutting of the reversely placed light-emitting master plate 01, thereby avoiding the cutting of a reversely placed light-emitting master plate 01 and resultant defective products after cutting.

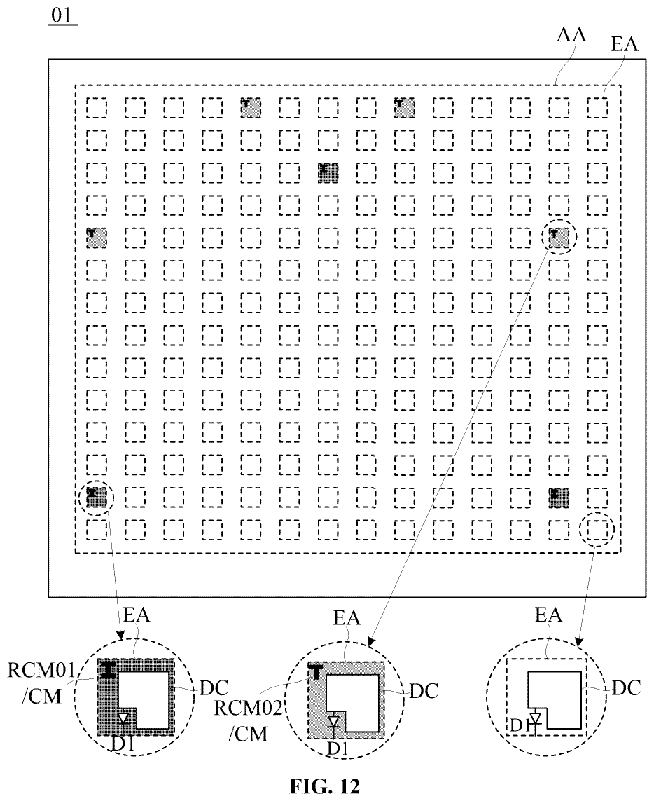

In one or more embodiments, FIG. 12 is a sixth top view illustrating the structure of a light-emitting master plate according to an embodiment of the present disclosure. With reference to FIG. 12, the cutting mark CM includes multiple first path cutting marks RCM01 and multiple second path cutting marks RCM02. The shape of the first path cutting mark RCM01 is different from the shape of the second path cutting mark RCM02.

Exemplarily, the first path cutting marks RCM01 in the same display area AA may correspond to a first cutting solution, and the cutting equipment may determine a first cutting path by identifying the first path cutting marks RCM01 and obtain a light-emitting panel of one shape by cutting the light-emitting master plate 01 according to the first cutting path. The second path cutting marks RCM02 in the same display area AA may correspond to a second cutting solution, and the cutting equipment may determine a second cutting path by identifying the second path cutting marks RCM02 and obtain a light-emitting panel of another shape by cutting the light-emitting master plate 01 according to the second cutting path. Multiple types of path cutting marks are provided in the display area AA, and each type of path cutting mark may correspond to a cutting solution so that the light-emitting master plate 01 can support multiple cutting solutions and obtain light-emitting panels of multiple shapes. Moreover, among the multiple types of path cutting marks, the position of a path cutting mark corresponding to a cutting solution can be quickly identified, thereby achieving rapid and precise positioning of the cutting path and improving cutting efficiency.

It should be understood that in addition to the first path cutting mark RCM01 and the second path cutting mark RCM02, the cutting marks CM in the same display area AA may also include a third path cutting mark, a fourth path cutting mark, or other path cutting marks to achieve multiple cutting solutions.

In one or more embodiments, the first path cutting mark RCM01 and the second path cutting mark RCM02 may be disposed in the hollow structures of different signal lines, respectively; the first path cutting mark RCM01 and the second path cutting mark RCM02 may be disposed in the same light-emitting area EA, or the first path cutting mark RCM01 and the second path cutting mark RCM02 may also be disposed in different light-emitting areas EA.

In one or more embodiments, the first path cutting mark RCM01 and the second path cutting mark RCM02 may be disposed in the hollow structures of the same-layer signal line. That is, the first path cutting mark RCM01 and the second path cutting mark RCM02 may be made in the same process, which can reduce the need for modifying the cutting mark masks and reduce production costs.

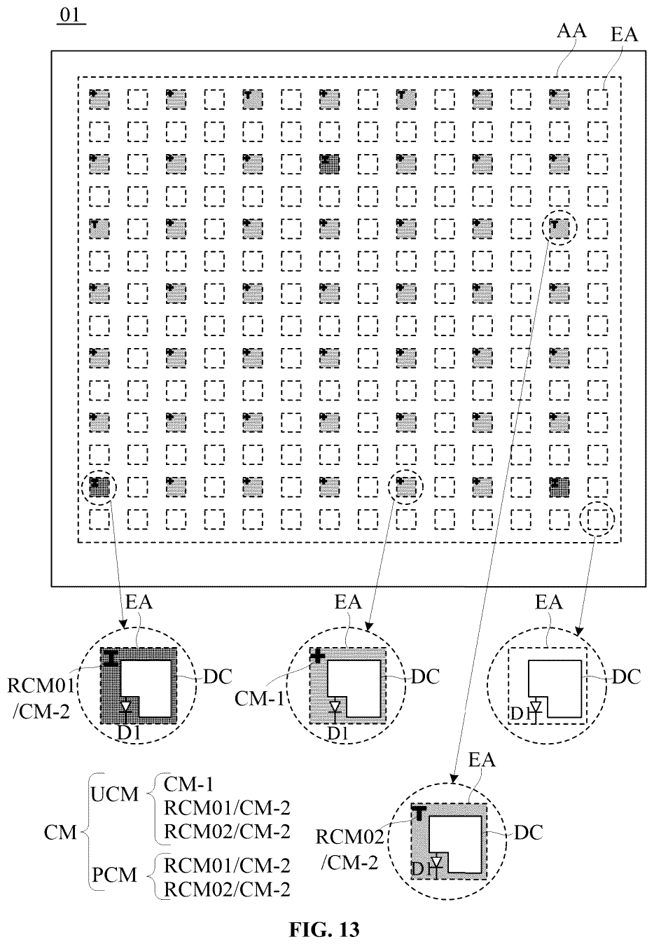

On the basis of the preceding embodiments, FIG. 13 is a seventh top view illustrating the structure of a light-emitting master plate according to an embodiment of the present disclosure. With reference to FIG. 13, the cutting mark CM further includes a universal cutting mark UCM, and the universal cutting mark UCM at least includes a first cutting mark CM-1. The shape of the first cutting mark CM-1 is different from both the shape of the first path cutting mark RCM01 and the shape of the second path cutting mark RCM02. In the same display area AA, the number of the first cutting marks CM-1 is greater than the number of the first path cutting marks RCM01, and/or the number of the first cutting marks CM-1 is greater than the number of the second path cutting marks RCM02.

The cutting mark CM also includes a first cutting mark CM-1. The shape of the first cutting mark CM-1 is different from both the shape of the first path cutting mark RCM01 and the shape of the second path cutting mark RCM02. A larger number of first cutting marks CM-1 are provided. The first cutting mark CM-1 may be used as a universal cutting mark UCM. Unlike the first path cutting mark RCM01 and the second path cutting mark RCM02, multiple universal cutting marks UCM in the same display area AA may correspond to multiple cutting solutions, and multiple universal cutting marks UCM in the same display area AA may determine multiple cutting paths to obtain light-emitting panels of multiple shapes. Thus, in addition to achieving rapid and precise positioning of multiple common cutting paths, this configuration also achieves flexible design of cutting paths and facilitates increased product diversity of the light-emitting master plate 01 to satisfy market demands.

In one or more embodiments, the first path cutting mark RCM01 and/or the second path cutting mark RCM02 are also able to be used as a universal cutting mark UCM, which helps reduce the number of cutting marks CM in the display area AA, simplifies the design of the cutting mark mask, and reduces the impact of the cutting marks CM on structures such as the light-emitting elements D1 and the driver circuits DC.

In one or more embodiments, the first path cutting mark RCM01 and/or the second path cutting mark RCM02 may also be reused as the second cutting mark CM-2. That is, the first path cutting mark RCM01 and/or the second path cutting mark RCM02 are also able to be used as a positioning cutting mark PCM, thereby achieving rapid positioning of the cutting marks CM needed for cutting and facilitating precise cutting.

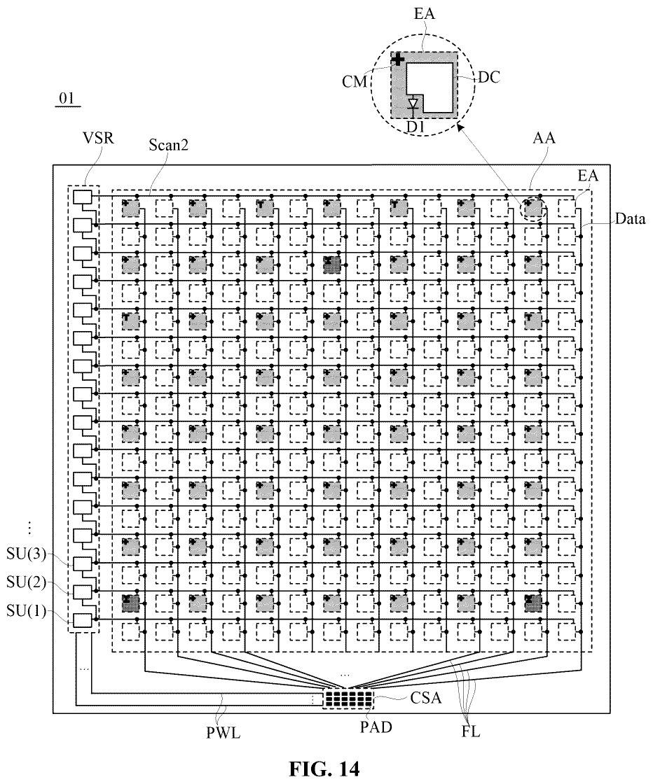

In one or more embodiments, FIG. 14 is an eighth top view illustrating the structure of a light-emitting master plate according to an embodiment of the present disclosure. With reference to FIG. 14, the light-emitting master plate 01 also includes a shift register VSR that is disposed corresponding to the display area and a chip setting area CSA that is disposed corresponding to the display area AA. The light-emitting master plate 01 also includes multiple panel wires PWL located outside the display area AA. The chip setting area CSA also includes multiple bonding pads PAD. At least part of the panel wires PWL are used to connect the shift register VSR and the bonding pad PAD in the chip setting area CSA. The shift register VSR includes multiple shift register units SU cascaded in sequence. A first-stage shift register unit SU (1) is located on a side of the shift register VSR closer to the chip setting area CSA.

Exemplarily, the chip setting area CSA is located below the display area AA, and the multiple bonding pads PAD in the chip setting area CSA may be used to bond and connect a display chip. The display chip may receive image data and convert the image data into corresponding timing control signals and data signals. The panel wires PWL may connect the bonding pads PAD in the chip setting area CSA and the shift register units in the shift register VSR and are used to transmit signals such as power signals, clock signals, and initial signals, thereby controlling the sequence, potential, or other properties of the output signals of each shift register unit SU.

The input end of the first-stage shift register unit SU(1) of the shift register VSR may be electrically connected to the bonding pads PAD in the chip setting area CSA through the panel wires PWL. Starting from the second-stage shift register unit SU(2), the input end of each shift register unit SU may be electrically connected to the output end of the previous-stage shift register unit SU, thereby achieving the sequential shifting of the signal. The output end of each shift register unit SU in the shift register VSR may also be electrically connected to a respective second scanning signal line Scan2 in the display area AA. The multiple shift register units SU cascaded in sequence in the shift register VSR can provide sequentially shifted second scanning signals to the multiple second scanning signal lines Scan2 in the display area AA, enabling row-by-row refresh of the driver circuits DC in each row of light-emitting areas EA. In an embodiment, the light-emitting master plate 01 also includes multiple fan-out wires FL that may be used to connect the driver circuits DC in the light-emitting areas EA and the bonding pads PAD in the chip setting area CSA for transmitting data signals.

The first-stage shift register unit SU(1) is located on a side of the shift register VSR closer to the chip setting area CSA so that the signal output by each shift register unit SU starts from the side closer to the chip setting area CSA and gradually cascades and shifts toward the side farther from the chip setting area CSA. The shift register units SU in the shift register VSR on the side farther from the chip setting area CSA may be cut. That is, when part circuit structures on the side of the shift register VSR farther from the chip setting area CSA are cut away, the part circuit structures on the side of the shift register VSR closer to the chip setting area CSA remain uncut and are still able to function normally. The uncut shift register units SU are able to continue to provide second scanning signals to the uncut driver circuits DC.

It should be understood that the shift register VSR may also be used to provide sequentially shifted first scanning signals or light emission control signals, and each shift register unit SU may also be connected to a respective first scanning signal line Scan1 or light emission control signal line Emit, which are not individually described or shown.

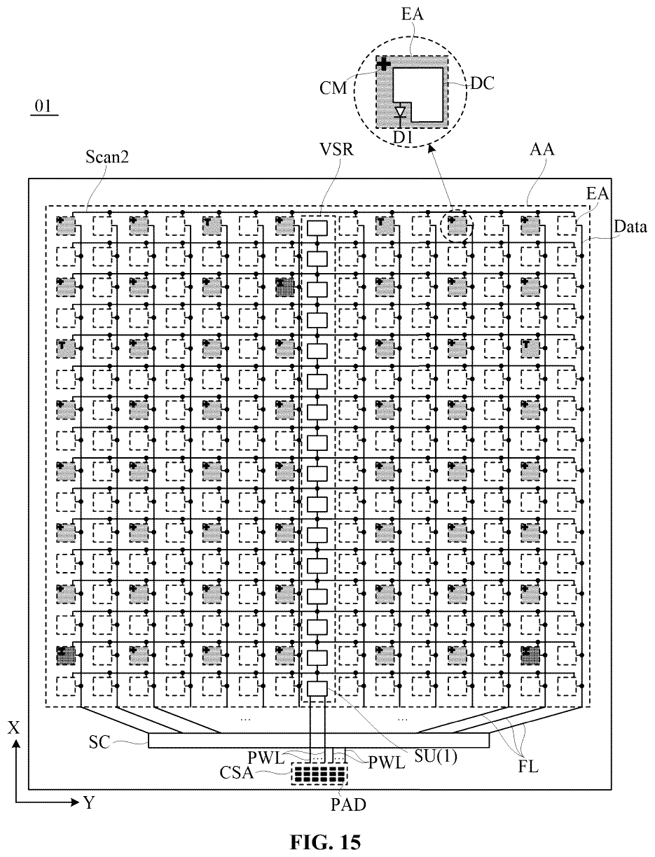

In one or more embodiments, FIG. 15 is a ninth top view illustrating the structure of a light-emitting master plate according to an embodiment of the present disclosure. With reference to FIG. 15, the shift register VSR that is disposed corresponding to the display area AA is disposed in the display area AA. The display area AA and the chip setting area CSA that are disposed corresponding to each other are arranged along a first direction X. The shift register VSR and the chip setting area CSA that are disposed corresponding to the same display area AA are also arranged along the first direction X.

Exemplarily, the chip setting area CSA disposed correspondingly is located in the middle area below the display area AA, and the display area AA and the chip setting area CSA that are disposed corresponding to each other may be arranged along the column direction. The shift register VSR may be located in the middle position of the display area AA and extend along the column direction, and the shift register VSR and the chip setting area CSA may also be arranged along the column direction. In the driver circuits DC in the same row of light-emitting areas EA, the driver circuits DC located on the left and right sides of the shift register VSR may be connected to the same-stage shift register unit SU through a signal line. The shift register VSR is disposed in the display area AA and above the chip setting area CSA so that part of the light-emitting areas EA on the left and right sides of the display area AA can be cut. When part of the light-emitting areas EA on the left and right sides of the display area AA are cut away, the shift register VSR located in the middle position of the display area AA remains uncut, enabling the driver circuits DC in the uncut light-emitting areas EA in the middle to still function normally. In this way, the following situation can be avoided: when the chip setting area CSA is disposed to the right side below the display area AA, the shift register VSR is disposed on the left side of the display area AA, and the structures near the left side of the display area AA are cut away, part of the shift register units SU are cut away, the driver circuits DC in the uncut light-emitting areas EA on the right side fail to function normally, and the yield of the cut product is affected (since the chip setting area CSA is disposed to the right side below the display area AA, the light-emitting areas EA on the right side of the display area AA are generally not cut away, while the light-emitting areas EA on the left side of the display area AA may be cut away).

It should be understood that if the chip setting area CSA is located in the middle below the display area AA, the shift register VSR may be located in the middle position of the display area AA; if the chip setting area CSA is located on the left or right side below the display area AA, the shift register VSR is also located on the left or right side of the display area AA. This configuration ensures that the shift register VSR and the chip setting area CSA in the cut light-emitting panel can be normally connected and enables the driver circuits DC in the cut light-emitting panel to normally receive the signals output by the shift register units SU of the shift register VSR, thereby improving product yield.

In one or more embodiments, with continued reference to FIG. 15, the light-emitting master plate 01 also includes a source circuit SC disposed corresponding to the display area AA. The source circuit SC is located on a side of the display area AA. The display area AA and the source circuit SC that are disposed corresponding to each other are arranged along a first direction X. A second direction Y intersects with the first direction. The length of the source circuit SC in the second direction Y is less than the length of the display area AA in the second direction Y.

Exemplarily, the source circuit SC may be electrically connected to the bonding pads PAD in the chip setting area CSA through panel wires PWL and receive digital image data from the display chip. The source circuit SC may convert the received digital image data into data signals for each driver circuit DC and provide them to each data signal line Data in a time-sharing manner through fan-out wires FL. The data signal lines Data may extend along the first direction X and be arranged along the second direction Y. The length of the source circuit SC in the second direction Y is set to be less than the length of the display area AA in the second direction Y so that the light-emitting areas EA located on two sides of the display area AA in the second direction Y can be cut away without damaging the source circuit SC. This configuration facilitates multiple cutting solutions while ensuring that the cut light-emitting panel can still function normally. In an embodiment, the first direction X is the column direction, and the second direction Y is the row direction.

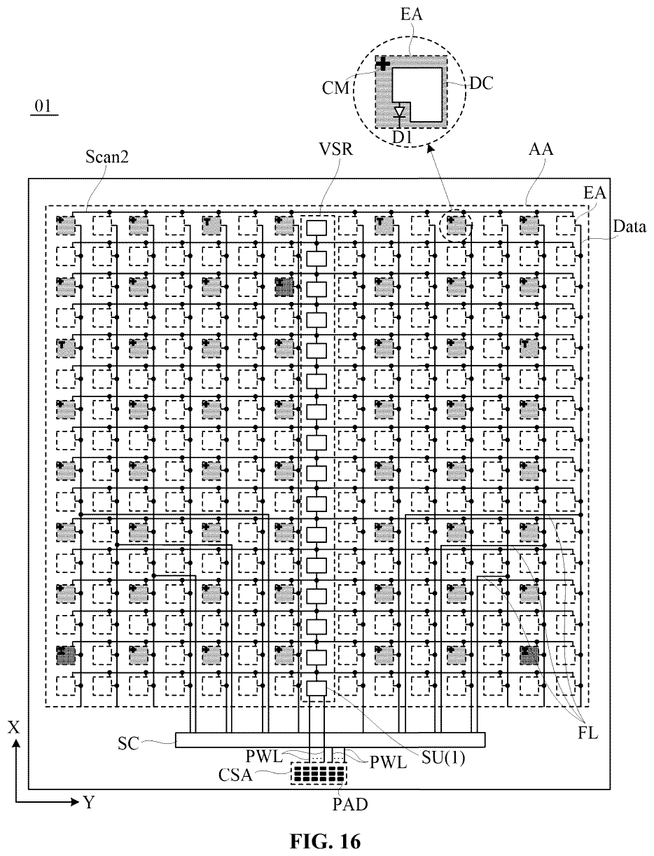

On the basis of the preceding embodiments, FIG. 16 is a tenth top view illustrating the structure of a light-emitting master plate according to an embodiment of the present disclosure. With reference to FIG. 16, part of fan-out wires FL connecting the data signal lines Data and the source circuit SC are located in the display area AA.

Exemplarily, along the second direction Y, the data signal lines Data near two side edges of the display area AA may be electrically connected to the source circuit SC through fan-out wires FL at least partially located in the display area AA. This configuration can reduce the wiring demand outside the display area AA, lower manufacturing difficulty, and ensure that when the light-emitting areas EA located at two side edges of the display area AA in the second direction Y and closer to the source circuit SC are cut away, the driver circuits DC in the light-emitting areas EA located at two side edges of the display area AA in the second direction Y and farther from the source circuit SC can still normally receive data signals, thereby achieving normal operation of all driver circuits DC and facilitating multiple cutting solutions.

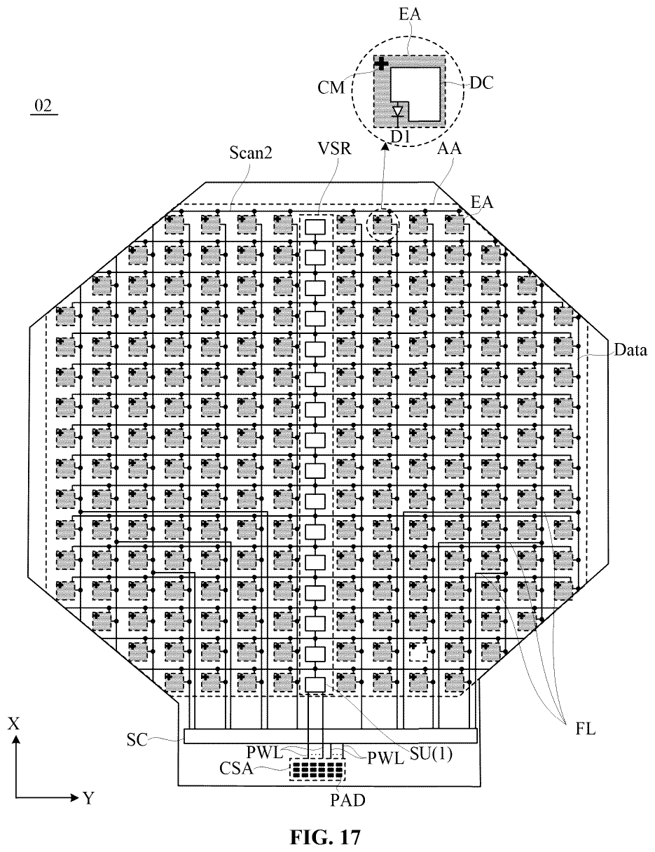

Based on the same inventive concept, an embodiment of the present disclosure further provides a light-emitting panel formed by cutting the light-emitting master plate 01 provided by any embodiment of the present disclosure. FIG. 17 is a first top view illustrating the structure of a light-emitting panel according to an embodiment of the present disclosure. With reference to FIG. 17, the light-emitting panel 02 includes a display area AA. Multiple light-emitting areas EA are disposed in the display area. The light-emitting area EA includes a light-emitting element D1 and a driver circuit DC. At least part of the light-emitting areas EA are provided with a cutting mark CM.

In an embodiment, the light-emitting panel 02 may be a display panel that directly displays images. In another embodiment, the light-emitting panel 02 may also be a backlight panel and displays images through a liquid crystal layer, a filter layer, or other layers. For example, the light-emitting panel 02 may be used as a backlight source for a liquid crystal display.

Before cutting, the cutting marks CM in the light-emitting master plate 01 are redundant to achieve special-shaped cutting. That is, cutting requires only part of all the cutting marks CM. Therefore, after cutting, the light-emitting panel 02 still contains uncut cutting marks CM.

Exemplarily, part of the cutting marks CM in the light-emitting master plate 01 may determine the cutting position and the cutting path, and the light-emitting panel 02 is obtained after the light-emitting master plate 01 is cut. The cutting marks CM in the cut light-emitting panel 02 may be used to re-determine the cutting position and cutting path for further cutting of the light-emitting panel 02, that is, secondary processing of the light-emitting panel 02. For example, for an already manufactured light-emitting panel 02 that no longer meets market demands, secondary processing is able to be performed to form a new shape to satisfy market demands, which helps to reduce product inventory and costs.

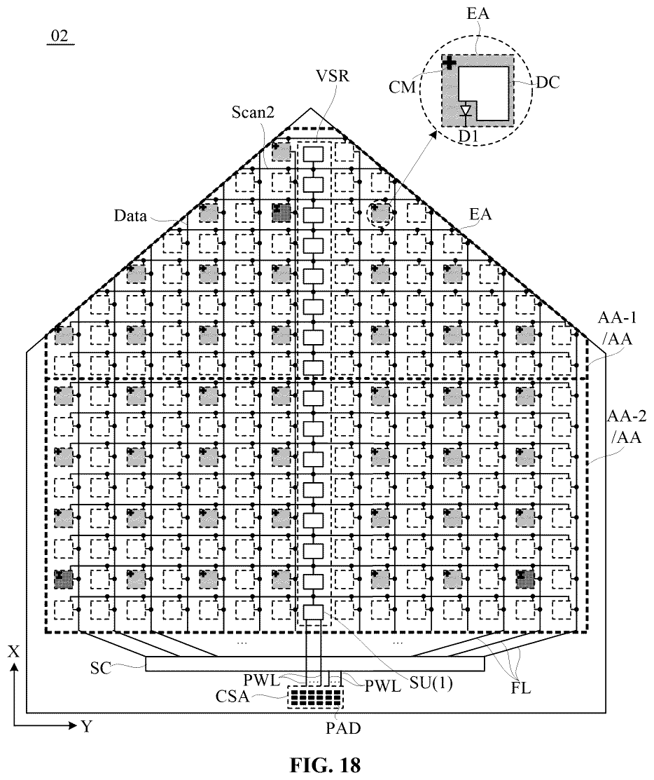

In one or more embodiments, FIG. 18 is a second top view illustrating the structure of a light-emitting panel according to an embodiment of the present disclosure. With reference to FIG. 18, the light-emitting panel 02 also includes a chip setting area CSA, and the display area AA and the chip setting area CSA are arranged along a first direction X. A second direction Y intersects with the first direction X. The display area AA includes a first sub-display area AA-1 and a second sub-display area AA-2 arranged along the first direction X. The second sub-display area AA-2 is located on a side of the first sub-display area AA-1 closer to the chip setting area CSA. The length of the second sub-display area AA-2 in the second direction Y is greater than or equal to the length of the first sub-display area AA-1 in the second direction Y.

Exemplarily, with reference to FIG. 18, the first direction X may be the column direction, and the second direction Y may be the row direction. In two adjacent rows of light-emitting areas EA, the number of light-emitting areas EA in the row closer to the chip setting area CSA is greater than or equal to the number of light-emitting areas EA in the row farther from the chip setting area CSA. When the chip setting area CSA is located below the display area AA, the width of the display area AA in the upper position may be less than the width of the display area AA in the lower position, but the width of the display area AA in the lower position cannot be less than the width of the display area AA in the upper position. In this manner, it is ensured that the part of the data signal lines Data closer to the chip setting area CSA are not cut away, and the retained data signal lines Data after cutting can all receive data signals, the situation where only the part of a data signal line Data closer to the chip setting area CSA is cut away is avoided, thereby avoiding the situation where the part of the same data signal line Data farther from the chip setting area CSA is unable to receive data signals and part of driver circuits DC in the light-emitting areas EA fail to function normally.

It should be noted that when the chip setting area CSA is located below the display area AA, FIG. 18 only exemplarily illustrates that the upper half of the display area AA is cut away. In other embodiments, the left or right side of the display area AA may also be cut away, provided that the width in the row direction of the retained display area AA closer to the chip setting area CSA is greater than or equal to the width in the row direction of the retained display area AA farther from the chip setting area CSA.

It should also be noted that FIG. 18 only exemplarily illustrates that the chip setting area CSA is located below the display area AA. In other optional embodiments, the chip setting area CSA may also be located above, to the left, or to the right of the display area AA. When the chip setting area CSA is located to the left of the display area AA, the length in the column direction of the retained display area AA closer to the chip setting area CSA should be greater than or equal to the length in the column direction of the retained display area AA farther from the chip setting area CSA.

On the basis of the preceding embodiments, with continued reference to FIG. 18, the maximum length of the display area AA in the second direction Y is greater than or equal to the maximum length of the chip setting area CSA in the second direction Y.

Exemplarily, an example where the first direction X is the column direction, the second direction Y is the row direction, and the chip setting area CSA is located below the display area AA is still used for illustration. With reference to FIG. 18, the maximum length of the display area AA in the second direction Y is the width in the row direction of the part of the display area AA closest to the chip setting area CSA. The maximum length of the display area AA in the second direction Y is set to be greater than or equal to the maximum length of the chip setting area CSA in the second direction Y so that the chip setting area CSA is not cut to prevent the chip setting area CSA from being cut, thereby avoiding the impact of cutting the chip setting area CSA on the connection between the display chip and the light-emitting panel 02 and the impact on the functionality of the light-emitting panel 02.

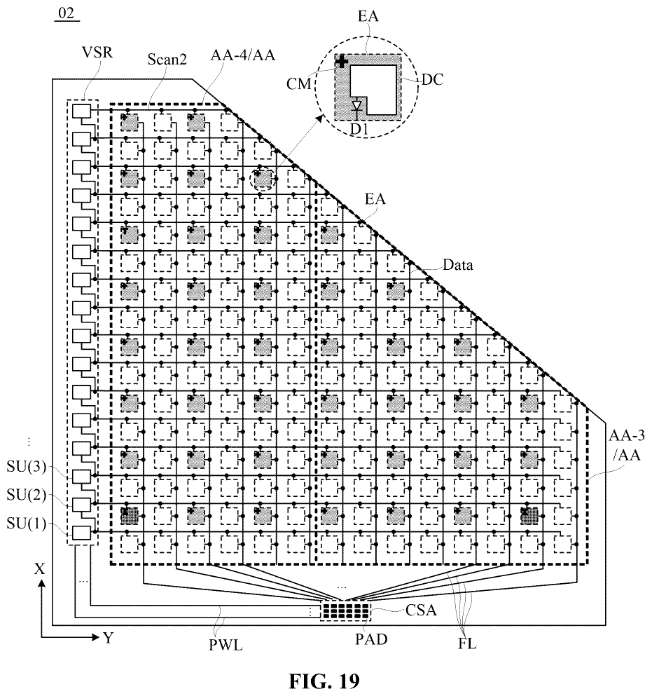

On the basis of the preceding embodiments, FIG. 19 is a third top view illustrating the structure of a light-emitting panel according to an embodiment of the present disclosure. With reference to FIG. 19, the light-emitting panel 02 also includes a shift register VSR. The display area AA includes a third sub-display area AA-3 and a fourth sub-display area AA-4 that are located on one side of the shift register VSR and arranged along the second direction Y. The fourth sub-display area AA-4 is located on a side of the third sub-display area AA-3 closer to the shift register VSR. The length of the fourth sub-display area AA-4 in the first direction X is greater than or equal to the length of the third sub-display area AA-3 in the first direction X.

The third sub-display area AA-3 and the fourth sub-display area AA-4 in the same display area AA are located on the same side of the shift register VSR.

Exemplarily, an example where the first direction X is the column direction, the second direction Y is the row direction, and the shift register units SU of the shift register VSR are electrically connected to the second scanning signal lines Scan2 in the display area AA is still used for illustration. In two adjacent columns of light-emitting areas EA, the number of light-emitting areas EA in the column closer to the shift register VSR is greater than or equal to the number of light-emitting areas EA in the column farther from the shift register VSR. When the chip setting area CSA is located to the left of the display area AA, the width of the display area AA in the left position may be greater than the width of the display area AA in the right position, but the width of the display area AA in the right position cannot be greater than the width of the display area AA in the left position. In this manner, it is ensured that the part of the second scanning signal lines Scan2 closer to the shift register VSR are not cut away, and the retained second scanning signal lines Scan2 after cutting can all receive the second scanning signals provided by the shift register units SU, the situation where only the part of a second scanning signal line Scan2 closer to the shift register VSR is cut away is avoided, thereby avoiding the situation where the part of the same second scanning signal line Scan2 farther from the shift register VSR is unable to receive the second scanning signal and part of driver circuits DC in the light-emitting areas EA fail to function normally.

It should be noted that when the shift register VSR is located to the left of the display area AA, FIG. 19 only exemplarily illustrates that the right half of the display area AA is cut away. In other exemplary embodiments, the upper side of the display area AA may also be cut away, provided that the length in the column direction of the retained display area AA closer to the shift register VSR is greater than or equal to the length in the column direction of the retained display area AA farther from the shift register VSR.

The light-emitting panel provided by the embodiments of the present disclosure is formed by cutting the light-emitting master plate provided by any embodiment of the present disclosure and possesses the corresponding technical features and beneficial effects of the light-emitting master plate. For details not exhaustively described in the embodiments of the light-emitting panel, reference may be made to the description of the light-emitting master plate above, which is not repeated here. Similarly, the light-emitting master plate of the embodiments of the present disclosure also possesses the functional modules and beneficial effects of the light-emitting panel. For details not exhaustively described in the embodiments of the light-emitting master plate, reference may be made to the description of the light-emitting panel above, which is not repeated here.

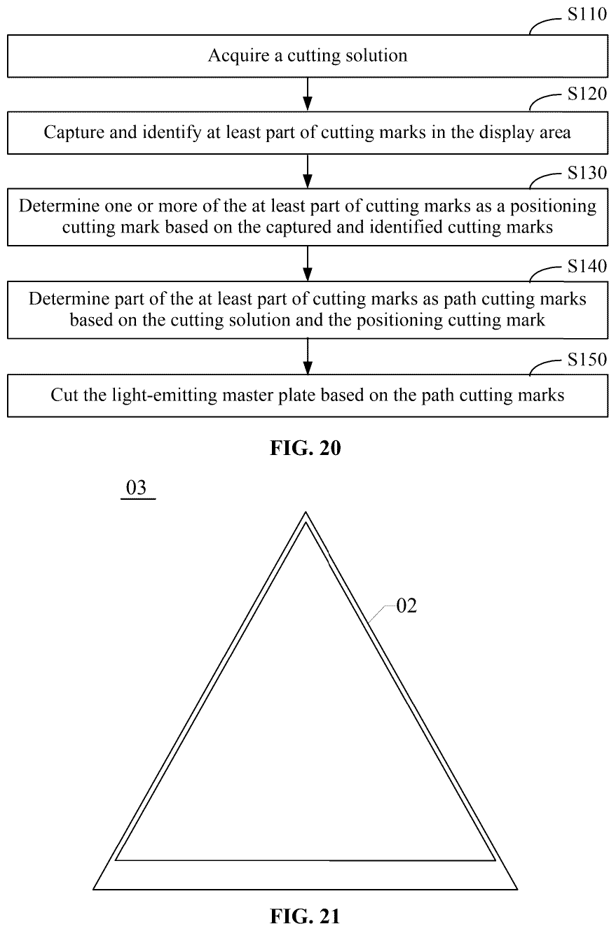

Based on the same inventive concept, an embodiment of the present disclosure also provides a cutting method for a light-emitting master plate used for cutting the light-emitting master plate provided by any embodiment of the present disclosure. FIG. 20 is a flowchart of a cutting method for a light-emitting master plate according to an embodiment of the present disclosure. With reference to FIG. 20, the cutting method includes S110 to S150.

In S110, a cutting solution is acquired.

In S120, at least part of cutting marks in the display area are captured and identified.

In S130, one or more of the at least part of cutting marks are determined as a positioning cutting mark based on the captured and identified cutting marks.

In S140, part of the at least part of cutting marks are determined as path cutting marks based on the cutting solution and the positioning cutting mark.

In S150, the light-emitting master plate is cut based on the path cutting marks.

Exemplarily, first, a cutting solution is designed based on customer requirements, and it is determined which of all the cutting marks are needed to determine the cutting path for the cutting solution. Then, part or all of the cutting marks in the display area are captured and identified. For example, cutting marks at special positions or with special shapes are selected as positioning cutting marks to determine the position of the light-emitting master plate, and the cutting marks needed for cutting are determined as path cutting marks based on the cutting solution. The cutting path and cutting position may be determined based on the path cutting marks, and the light-emitting master plate is cut accordingly to obtain a light-emitting panel. In this manner, multiple cutting solutions are achieved, and only the necessary cutting marks are selected to form the cutting path based on the cutting solution and the positioning cutting mark, which facilitates accurate cutting.

In one or more embodiments, determining the position of the light-emitting master plate through the positioning cutting mark or determining the position of the path cutting marks through the positioning cutting mark includes taking the positioning cutting mark as the coordinate origin to determine the position of the light-emitting master plate or the position of the path cutting marks.

In one or more embodiments, cutting the light-emitting master plate based on the path cutting marks includes determining a cutting path based on the path cutting marks, where at least part of the cutting path extends along a row direction, and/or at least part of the cutting path extends along a column direction; and cutting the light-emitting master plate along the cutting path.

The cutting path can extend along the row direction or the column direction. This configuration prevents the cutting path from extending in a diagonal direction and helps reduce damage to the light-emitting elements and pixel driver circuits during the cutting process.

In one or more embodiments, determining the cutting path based on the path cutting marks includes taking a position of each of the path cutting marks as a starting point, moving a first moving distance in a third direction to determine multiple cutting points, where the third direction is parallel to a plane where the light-emitting master plate is located; and determining the cutting path based on the cutting points, where each of the multiple cutting points is located on the cutting path.

The third direction parallel to the plane where the light-emitting master plate is located may be the row direction, the column direction, or a direction intersecting both the row direction and the column direction, which is not limited by the embodiments of the present disclosure.

Exemplarily, after the path cutting marks are determined, the path formed by the path cutting marks may be offset by a certain distance to the left, right, up, or down. For example, if the cutting mark is in the upper left corner of a pixel, the path of the path cutting marks may be offset to the left and upward by a certain distance. In this case, the third direction is from the lower right to the upper left corner so that the cutting path does not pass through the path cutting marks but is located near the path cutting marks, thereby avoiding the cutting of the light-emitting elements and driver circuits in the light-emitting area.

The cutting method for the light-emitting master plate provided by the embodiments of the present disclosure is used to cut the light-emitting master plate provided by any embodiment of the present disclosure and possesses the technical features and beneficial effects of the light-emitting master plate. For details not exhaustively described in the embodiments of the cutting method for the light-emitting master plate, reference may be made to the description of the light-emitting master plate above, which is not repeated here. Similarly, the light-emitting master plate of the embodiments of the present disclosure also possesses the functional modules capable of performing the cutting method for the light-emitting master plate and beneficial effects provided by the embodiments of the present disclosure. For details not exhaustively described in the embodiments of the light-emitting master plate, reference may be made to the description of the cutting method for the light-emitting master plate above, which is not repeated here.

Based on the same disclosure concept, an embodiment of the present disclosure also provides a display device. FIG. 21 is a diagram illustrating the structure of a display device according to an embodiment of the present disclosure. As shown in FIG. 21, the display device 03 includes the light-emitting panel 02 provided by any embodiment of the present disclosure. The display device 03 provided by the embodiments of the present disclosure may be a triangular display device as shown in FIG. 21, or a special-shaped display device such as circular, rounded rectangular, or trapezoidal. The display device 03 provided by the embodiments of the present disclosure may be any electronic product with a display function, including but not limited to the following categories: a television, a laptop, a desktop display, a tablet computer, a digital camera, a smart bracelet, smart glasses, a vehicle-mounted display, a medical device, an industrial control device, and a touch interactive terminal, and no special limitations are imposed thereto in the embodiments of the present disclosure.

It is to be noted that the above are only preferred embodiments of the present disclosure and the technical principles used therein. It is to be understood by those skilled in the art that the present disclosure is not limited to the embodiments described herein. For those skilled in the art, various apparent modifications, adaptations, and substitutions can be made without departing from the scope of the present disclosure. Therefore, while the present disclosure is described in detail in connection with the preceding embodiments, the present disclosure is not limited to the preceding embodiments and may include equivalent embodiments without departing from the concept of the present disclosure. The scope of the present disclosure is determined by the scope of the appended claims.

What is claimed is:

1. A light-emitting master plate, comprising: at least one display area and a plurality of light-emitting areas arranged in an array in a display area of the at least one display area;
wherein a light-emitting area of the plurality of light-emitting areas comprises a light-emitting element and a driver circuit; and
at least part of the plurality of light-emitting areas are provided with a cutting mark.

2. The light-emitting master plate according to claim 1, wherein the light-emitting master plate satisfies at least one of the following:
in a row where a light-emitting area provided with the cutting mark is located, at least two light-emitting areas are each provided with the cutting mark; or
in a column where a light-emitting area provided with the cutting mark is located, at least two light-emitting areas are each provided with the cutting mark.

3. The light-emitting master plate according to claim 2, wherein the light-emitting master plate satisfies at least one of the following:
among light-emitting areas located in a same row, at least two of the light-emitting areas are each provided with the cutting mark; or
among light-emitting areas located in a same column, at least two of the light-emitting areas are each provided with the cutting mark.

4. The light-emitting master plate according to claim 1, wherein the light-emitting master plate satisfies at least one of the following:
each of the plurality of light-emitting areas located in the display area is provided with the cutting mark; or
each of light-emitting areas located at an edge of the display area is provided with the cutting mark.

5. The light-emitting master plate according to claim 1, wherein the light-emitting area comprises a plurality of light-emitting elements and a plurality of driver circuits; and
a light-emitting area provided with the cutting mark has one cutting mark.

6. The light-emitting master plate according to claim 5, wherein the light-emitting area comprises a first edge and a second edge that are adjacent to each other, the light-emitting area comprises a plurality of sub-light-emitting areas, and a sub-light-emitting area of the plurality of sub-light-emitting areas comprises one light-emitting element and one driver circuit;
a sub-light-emitting area adjacent to both the first edge and the second edge is a first sub-light-emitting area; and
the first sub-light-emitting area is provided with the cutting mark, and in the first sub-light-emitting area, the cutting mark is located on at least one of: a side of the driver circuit closer to the first edge, or a side of the driver circuit closer to the second edge.

7. The light-emitting master plate according to claim 1, further comprising a plurality of first signal lines located in the display area;
wherein a first signal line of the plurality of first signal lines is electrically connected to at least part of driver circuits; and
at least part of the plurality of first signal lines comprise a hollow structure, and the cutting mark is disposed in the hollow structure;
wherein the first signal line is used for transmitting a signal of a fixed potential.

8. The light-emitting master plate according to claim 1, wherein the cutting mark comprises a universal cutting mark and a positioning cutting mark, the universal cutting mark at least comprises a first cutting mark, the positioning cutting mark comprises a second cutting mark, and a shape of the first cutting mark is different from a shape of the second cutting mark; and
in a same display area, a number of first cutting marks is greater than a number of second cutting marks.

9. The light-emitting master plate according to claim 1, wherein the cutting mark comprises a plurality of first path cutting marks and a plurality of second path cutting marks; and
a shape of a first path cutting mark of the plurality of first path cutting marks is different from a shape of a second path cutting mark of the plurality of second path cutting marks.

10. The light-emitting master plate according to claim 9, wherein the cutting mark further comprises a universal cutting mark, and the universal cutting mark at least comprises a first cutting mark;
a shape of the first cutting mark is different from both the shape of the first path cutting mark and the shape of the second path cutting mark; and
in a same display area, a number of first cutting marks is greater than at least one of: a number of first path cutting marks, or a number of second path cutting marks.

11. The light-emitting master plate according to claim 1, comprising a plurality of conductive layers and at least one active layer;
wherein a conductive layer of the plurality of conductive layers comprises a conductive structure, and an active layer of the at least one active layer comprises an active structure; and
in a direction perpendicular to a plane where the light-emitting master plate is located, a projection of the cutting mark on the plane where the light-emitting master plate is located does not overlap with a projection of the conductive structure in the driver circuit on the plane where the light-emitting master plate is located and a projection of the active structure on the plane where the light-emitting master plate is located.

12. The light-emitting master plate according to claim 1, further comprising a shift register that is disposed corresponding to the display area and a chip setting area that is disposed corresponding to the display area;
wherein the light-emitting master plate further comprises a plurality of panel wires located outside the display area, the chip setting area further comprises a plurality of bonding pads, and at least part of the plurality of panel wires are used to connect the shift register and a bonding pad of the plurality of bonding pads in the chip setting area; and
the shift register comprises a plurality of shift register units cascaded in sequence, wherein a first-stage shift register unit is located on a side of the shift register closer to the chip setting area.

13. The light-emitting master plate according to claim 1, further comprising a source circuit disposed corresponding to the display area;
wherein the source circuit is located on a side of the display area; and
the display area and the source circuit that are disposed corresponding to each other are arranged along a first direction, a second direction intersects with the first direction, and
a length of the source circuit in the second direction is less than a length of the display area in the second direction.

14. A light-emitting panel, comprising a display area;
wherein a plurality of light-emitting areas are disposed in the display area, and a light-emitting area of the plurality of light-emitting areas comprises a light-emitting element and a driver circuit; and
at least part of the plurality of light-emitting areas are provided with a cutting mark.

15. The light-emitting panel according to claim 14, further comprising a chip setting area;
wherein the display area and the chip setting area are arranged along a first direction, and a second direction intersects with the first direction;
the display area comprises a first sub-display area and a second sub-display area arranged along the first direction, and the second sub-display area is located on a side of the first sub-display area closer to the chip setting area; and
a length of the second sub-display area in the second direction is greater than or equal to a length of the first sub-display area in the second direction.

16. The light-emitting panel according to claim 15, further comprising a shift register;
wherein the display area comprises a third sub-display area and a fourth sub-display area that are located on a side of the shift register and arranged along the second direction, and the fourth sub-display area is located on a side of the third sub-display area closer to the shift register; and
a length of the fourth sub-display area in the first direction is greater than or equal to a length of the third sub-display area in the first direction.

17. A cutting method for a light-emitting master plate, used for cutting the light-emitting master plate according to claim 1;
wherein the cutting method comprises:
acquiring a cutting solution;
capturing and identifying at least part of cutting marks in the display area;
determining at least one cutting mark of the at least part of cutting marks as a positioning cutting mark based on the captured and identified cutting marks;
determining part of the at least part of cutting marks as path cutting marks based on the cutting solution and the positioning cutting mark; and
cutting the light-emitting master plate based on the path cutting marks.

18. The cutting method for the light-emitting master plate according to claim 17, wherein cutting the light-emitting master plate based on the path cutting marks comprises:
determining a cutting path based on the path cutting marks, wherein the cutting path satisfies at least one of the following: at least part of the cutting path extends along a row direction, or at least part of the cutting path extends along a column direction; and
cutting the light-emitting master plate along the cutting path.

19. The cutting method for the light-emitting master plate according to claim 18, wherein determining the cutting path based on the path cutting marks comprises:
taking a position of each of the path cutting marks as a starting point, moving a first moving distance in a third direction to determine a plurality of cutting points, wherein the third direction is parallel to a plane where the light-emitting master plate is located; and
determining the cutting path based on the plurality of cutting points, wherein each of the plurality of cutting points is located on the cutting path.

20. A display device, comprising a light-emitting panel;
wherein the light-emitting panel comprises at least one display area and a plurality of light-emitting areas arranged in an array in a display area of the at least one display area;
a light-emitting area of the plurality of light-emitting areas comprises a light-emitting element and a driver circuit; and
at least part of the plurality of light-emitting areas are provided with a cutting mark.
